(19) United States
(12) Patent Application Publication
(10) Pub. No.: US 2013/0134034 A1
(43) Pub. Date: May 30, 2013

(54) THIN FILM MANUFACTURING METHOD, THIN FILM MANUFACTURING DEVICE, AND LIQUID CRYSTAL DISPLAY DEVICE MANUFACTURING METHOD

(71) Applicant: Panasonic Liquid Crystal Display Co., Ltd., Himeji-shi (JP)

(72) Inventors: Hironobu INOUE, Hyogo (JP); Hiroaki YONEKURA, Hyogo (JP)

(73) Assignee: PANASONIC LIQUID CRYSTAL DISPLAY CO., LTD., Himeji-shi (JP)

(21) Appl. No.: 13/687,624

(22) Filed: Nov. 28, 2012

(30) Foreign Application Priority Data
Nov. 28, 2011 (JP) 2011-258804

(51) Int. Cl. C23C 14/35

(52) U.S. Cl. CPC C23C 14/35
USPC 204/192.15; 204/298.16

(57) ABSTRACT

Provided is a thin film manufacturing method which is capable of reducing foreign matters to be adhered to a substrate in number while lowering the arcing count. The thin film manufacturing method involves placing a magnet unit (5) which includes a first magnet (51) and a second magnet (52). The first magnet (51) has a first polarity on its top face which is opposed to a target (94). The second magnet (52) has a second polarity on its top face and is arranged around the first magnet (51). The method also involves reducing a closest distance between an edge (52a) of the magnet unit (5) and an edge (94a) of the target (94) in a Y-direction as an amount of the target (94) used increases.

### CROSS-REFERENCE TO RELATED APPLICATION

The present application claims priority from Japanese application JP2011-258804 filed on Nov. 28, 2011, the content of which is hereby incorporated by reference into this application.

### TECHNICAL FIELD

The present application relates to a thin film manufacturing method, a thin film manufacturing device, and a liquid crystal display device manufacturing method and, more particularly, to magnetron sputtering.

### BACKGROUND

Magnetron sputtering has been known as one of film forming methods. In magnetron sputtering, a substrate is opposed to one of faces of a target, which is a raw material of a thin film, and a magnet unit is opposed to the other face of the target. The magnet unit generates a magnetic field with which plasma is concentrated in the vicinity of the surface of the target, thereby being capable of enhancing the film formation speed. Magnetron sputtering sometimes involves swinging the magnet unit with respect to the target in order to enhance target utilization efficiency. Japanese Patent Application Laid-open No. 2009-74181 discloses a technology for forming a film of a transparent, conductive oxide on a substrate by magnetron sputtering.

### SUMMARY

As illustrated in FIG. 15, a surface of a target T has an erosion region E which is sputtered by plasma and a non-erosion region N which is not sputtered by plasma, and target particles flying out of the erosion region E adhere to the non-erosion region N. The non-erosion region N is formed along the edges of the target T. In the case of a target made of an oxide, target particles adhered to the non-erosion region N tend to fall off the surface of the target T and attach themselves to a surface of a substrate B as foreign matters. It is also a known fact that an increase in the amount of the target T used results in an increase in the number of foreign matters to be adhered to the surface of the substrate B.

In order to reduce the number of foreign matters to be adhered to the substrate B, it is preferred to reduce a distance L between an edge of the target T and an edge of a magnet unit M, thereby narrowing the non-erosion region N to which target particles adhere. However, the distance L that is too short increases the count of arcing in which charged particles in plasma flow into a grounded shield G, which is arranged around the target T.

The present implementation has been made in view of the circumstances described above, and a main object of the present implementation is to provide a thin film manufacturing method, a thin film manufacturing device, and a liquid crystal display device manufacturing method that are capable of reducing foreign matters to be adhered to a substrate in number while lowering the arcing count.

In one general aspect, the instant application describes a thin film manufacturing method for forming a thin film that is made of an oxide by sputtering of a target. The thin film manufacturing method includes placing a magnet unit which comprises a first magnet and a second magnet, the first magnet having a first polarity on its face that is opposed to a face of the target opposite to a target face where the target is sputtered, the second magnet having a second polarity on its face that is opposed to the face of the target opposite to the target face where the target is sputtered, the second magnet being disposed on each side of the first magnet; and reducing a closest distance between an edge of the magnet unit and an edge of the target in an in-plane direction as an amount of the target used increases.

In magnetron sputtering, plasma concentrates most on a point where the horizontal component of a magnetic field generated by the magnet unit (a component in the in-plane direction of the target) is 0. When the first magnet of the magnet unit is surrounded by the second magnet, the inner first magnet is capable of closing a magnetic field of a smaller volume on its own compared to the outer second magnet. A point where the horizontal component of a magnetic field between the first magnet and the second magnet is 0 therefore shifts outward as the distance from the magnet unit grows (see FIG. 2B). This means that a decrease in target thickness leads to an inward shift of a point where the target is sputtered most, thus expanding the non-erosion region (see FIGS. 6A and 6B).

The present implementation prevents the expansion of the non-erosion region while lowering the arcing count by reducing the closest distance in the in-plane direction between an edge of the magnet unit and an edge of the target as the used target amount increases. Foreign matters to be adhered to the substrate are thus reduced in number and target utilization efficiency is enhanced as well.

The above general aspect may include one or more of the following features. The first magnet may be formed to have a belt shape with longer sides, and the edge of the magnet unit is an edge of the second magnet, which is substantially parallel to the longer sides of the first magnet. This prevents the expansion of the non-erosion region in the width direction of the first magnet, and also enhances target utilization efficiency.

The magnet unit may be swung in the in-plane direction. This enhances target utilization efficiency.

At least one of the first magnet and the second magnet may comprise a plurality of aligned magnets. This gives more freedom in terms of the shape of the first magnet and the second magnet, depending on the arrangement of the plurality of magnets.

The first magnet may have a length in a direction perpendicular to longer sides of the first magnet, which is substantially equal to a total length in the perpendicular direction of the second magnet disposed on each side of the first magnet, in a plane of the magnet unit.

The thin film may be made of indium tin oxide (ITO). This provides an ITO thin film that is reduced in the number of foreign matters to be adhered thereto.

In another general aspect, a thin film manufacturing method for forming a thin film that is made of an oxide by sputtering of a target of the instant application, the thin film manufacturing method includes placing a magnet unit which includes a first magnet and a second magnet, the first magnet having a first polarity on its face that is opposed to a face of the target opposite to a target face where the target is sputtered, the second magnet having a second polarity on its face that is opposed to the face of the target opposite to the target face where the target is sputtered, the second magnet being disposed on each side of the first magnet; and increasing a closest distance between the magnet unit and the target in an out-of-plane direction as an amount of the target used increases.

According to the present implementation, the expansion of the non-erosion region is prevented while the arcing count is lowered by increasing the closest distance in the out-of-plane direction between the magnet unit and the target as the used target amount increases. Foreign matters to be adhered to the substrate are thus reduced in number and target utilization efficiency is enhanced as well.

The instant application describes another thin film manufacturing method for forming a thin film that is made of an oxide by sputtering of a target. Thin film manufacturing method includes placing a magnet unit which includes a first magnet and a second magnet, the first magnet having a first polarity on its face that is opposed to a face of the target opposite to a target face where the target is sputtered, the second magnet having a second polarity on its face that is opposed to the face of the target opposite to the target face where the target is sputtered, and arranging the magnet unit so that a point where a horizontal component of a magnetic field generated between the first magnet and the second magnet is zero is slanted toward the second magnet side as a distance from one of the face of the first magnet and the face of the second magnet to the target decreases; and controlling one of the target and the magnet unit so that a shortest distance between an outer stretch of a region in which the target is sputtered and edges of the target is substantially constant.

In one general aspect, the instant application describes a liquid crystal display device manufacturing method which includes manufacturing a thin film by the methods described above. According to the present implementation, the expansion of the non-erosion region is prevented by keeping substantially constant the shortest distance between the outer stretch of the region in which the target is sputtered and the edges of the target. Foreign matters to be adhered to the substrate are thus reduced in number and target utilization efficiency is enhanced as well.

According to the present implementation, there is provided a liquid crystal display device with a thin oxide film that is reduced in the number of foreign matters to be adhered thereto.

In another general aspect, the instant application describes a thin film manufacturing device for forming a thin film that is made of an oxide by sputtering of a target. The thin film manufacturing device includes a magnet unit which includes a first magnet and a second magnet, the first magnet having a first polarity on its face that is opposed to a face of the target opposite to a target face where the target is sputtered, the second magnet having a second polarity on its face that is opposed to the face of the target opposite to the target face where the target is sputtered, the second magnet being disposed on each side of the first magnet; and swinging means for swinging one of the target and the magnet unit relative to another thereof, the swinging means reducing a closest distance between an edge of the magnet unit and an edge of the target in an in-plane direction as an amount of the target used increases.

According to the present implementation, the expansion of the non-erosion region is prevented while the arcing count is lowered by reducing the closest distance in the in-plane direction between the edge of the magnet unit and the edge of the target as the used target amount increases. Foreign matters to be adhered to the substrate are thus reduced in number and target utilization efficiency is enhanced as well.

### BRIEF DESCRIPTION OF THE DRAWINGS

In the accompanying drawings:

FIG. 1 is a diagram schematically illustrating a thin film manufacturing device of the instant application;

FIG. 2A is a plan view of a magnet unit;

FIG. 2B is a sectional view of the magnet unit;

FIG. 3 is a plan view of a magnet unit according to a modified example;

FIG. 4 is a plan view of a magnet unit according to another modified example;

FIG. 5 is a diagram illustrating a first moving example of the magnet unit;

FIGS. 6A and 6B are diagrams illustrating the related art;

FIGS. 7A and 7B are diagrams illustrating a target state.

FIGS. 8A and 8B are diagrams illustrating the first moving example of the magnet unit;

FIGS. 9A and 9B are diagrams illustrating a target state;

FIG. 10 is a diagram illustrating a second moving example of the magnet unit;

FIGS. 11A and 11B are diagrams illustrating a third moving example of the magnet unit;

FIG. 12 is a graph showing an example of the relation between a used target amount and an edge-to-edge distance;

FIGS. 13A and 13B are graphs showing experiment results of Comparative Example;

FIGS. 14A and 14B are graphs showing experiment results of Example; and

FIG. 15 is a diagram illustrating the related art.

### DETAILED DESCRIPTION

A thin film manufacturing method, a thin film manufacturing device, and a liquid crystal display device manufacturing method according to an embodiment of the present implementation are described below with reference to the accompanying drawings.

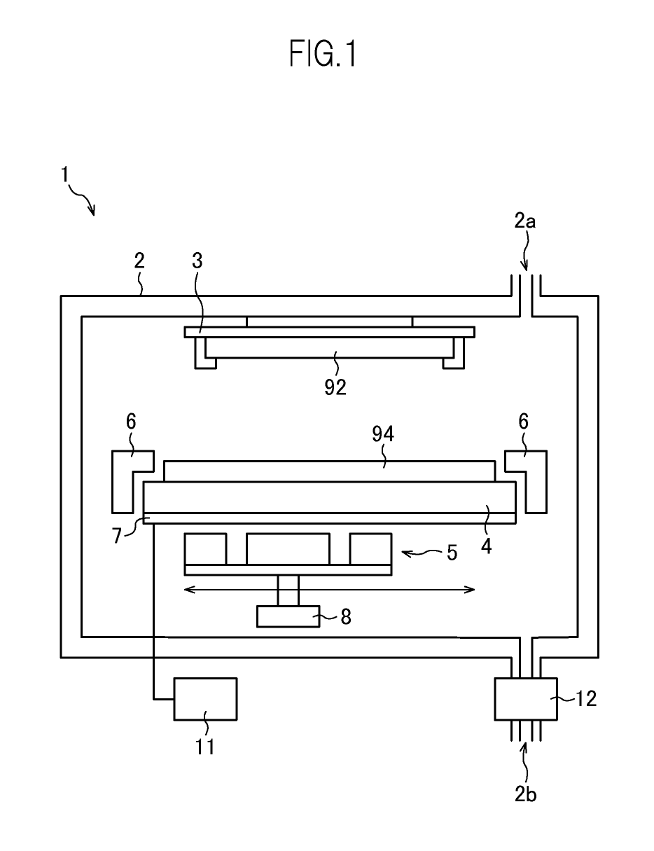

FIG. 1 is a diagram schematically illustrating a thin film manufacturing device 1 of the instance application. The thin film manufacturing device 1 is a device that executes magnetron sputtering. The thin film manufacturing device 1 has a chamber 2. There are placed inside the chamber 2 a tray 3 which supports a substrate 92, a plate 4 which supports a target 94, a magnet unit 5, and a grounded shield 6 which is arranged around the target 94. In the following description, a direction in which the substrate 92 is disposed in relation to the target 94 is the upper direction and a direction in which the magnet unit 5 is disposed in relation to the target 94 is the lower direction for convenience of description. In some practical uses, however, an edge of the target 94 is in the upper or lower direction.

The tray 3 which supports the substrate 92 supports the perimeter of the substrate 92 so that the bottom face of the substrate 92 is opposed to the top face of the target 94. A thin film is formed on the bottom face of the substrate 92 by executing magnetron sputtering. The plate 4 which supports the target 94 is provided with an electrode 7 which is connected to a power source 11 placed outside the chamber 2. The power source 11 outputs negative DC voltage or high frequency voltage in order to induce plasma inside the chamber 2.

The chamber 2 is provided with a gas inlet 2a and a gas outlet 2b. The gas outlet 2b is provided with a pump 12 for discharging gas from the inside of the chamber 2 to the outside. Magnetron sputtering is executed in an atmosphere that is obtained by forming a vacuum inside the chamber 2 and introducing rare gas such as Ar into the vacuum.

The magnet unit 5 quickens the speed at which the thin film is formed on the substrate 92 by forming a magnetic field in the vicinity of the top face of the target 94 and thus concentrating plasma in the vicinity of the top face of the target 94. A motor 8 is an example of a swinging unit, and swings the magnet unit 5 with respect to the target 94. Structural examples and moving examples of the magnet unit 5 are described later in detail.

In this embodiment, a thin film of a transparent, conductive oxide is formed on the bottom face of the substrate 92 by magnetron sputtering with the thin film manufacturing device 1. A representative oxide having transparent conductivity is tin-doped indium oxide (ITO). In this case, the target 94 is, for example, a sintered body of In₂O₃ or SnO₂. Other examples of the oxide include indium zinc oxide (IZO), zinc oxide (ZnO), and tin oxide (SnO₂).

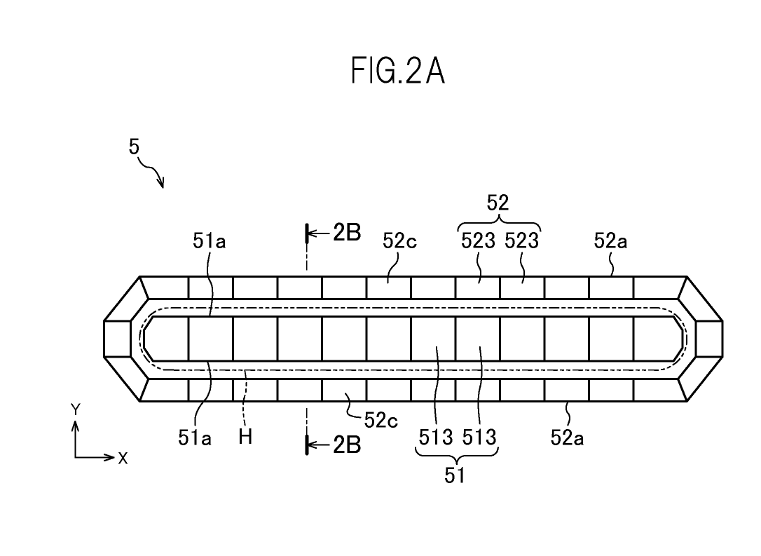

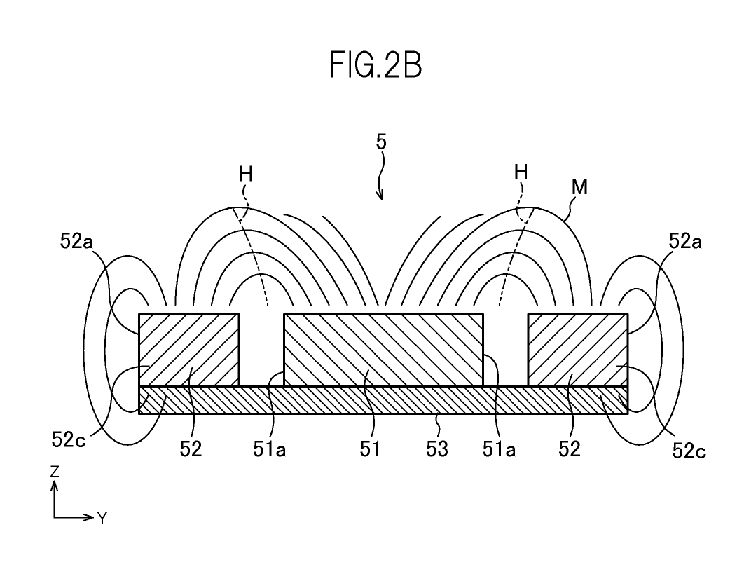

FIG. 2A is a plan view of the magnet unit 5. FIG. 2B is a sectional view of the magnet unit 5 taken along the break line in FIG. 2A. In the following description, an X-direction and a Y-direction are the in-plane direction of the target 94 and the magnet unit 5, and a Z-direction is the out-of-plane direction of the target 94 and the magnet unit 5 (i.e., a direction perpendicular to the top face of the target 94). FIG. 2B uses solid lines to express magnetic force lines M which represent a magnetic field generated by the magnet unit 5, and a dash-dot-dot line to express a line H which connects points where the horizontal component of a magnetic field is 0.

The magnet unit 5 includes a first magnet 51, a second magnet 52, which is arranged around the first magnet 51 in the in-plane direction to form a ring shape, and a plate 53 on which the first magnet 51 and the second magnet 52 are put. The first magnet 51 has a first polarity (for example, the N pole) on its top face which is opposed to the bottom face of the target 94, and has a second polarity (for example, the S pole) on its bottom face. The second magnet 52 has the second polarity on its top face which is opposed to the bottom face of the target 94, and the first polarity on its bottom face.

The first magnet 51 is constituted of a plurality of aligned, block-shaped magnets 513, and forms as a whole a belt shape, which is extended in the X-direction and has longer sides 51a running in the X-direction. The second magnet 52 is constituted of a plurality of aligned, block-shaped magnets 523, and forms as a whole a ring shape, which is extended in the X-direction and has a pair of longer-side portions 52c running in the X-direction. The longer-side portions 52c are disposed on each side of the first magnet 51 in the Y-direction.

The width of the first magnet 51 in the Y-direction is designed so as to be substantially equal to the total width in the Y-direction of the pair of longer-side portions 52c, which are included in the second magnet 52. The ends of the first magnet 51 in the X-direction and the ends of the second magnet 52 in the X-direction have a beveled shape so that the distance between the first magnet 51 and the second magnet 52 is uniformized. The second magnet 52 surrounding the first magnet 51 does not need to have a completely closed shape, and may have gaps in the plurality of magnets 523.

The magnet unit 5 described above generates a magnetic field that curves outward from the top face of the first magnet 51 toward the top face of the second magnet 52 (or vice versa) as illustrated in FIG. 2B. With the first magnet 51 surrounded by the second magnet 52, the magnetic field between the first magnet 51 and the second magnet 52 is formed basically radially. However, a magnetic field between the first magnet 51 and one of the longer-side portions 52c and a magnetic field between the first magnet 51 and the other of the longer-side portions 52c are formed mainly along the Y-direction because the first magnet 51 and the pair of longer-side portions 52c of the second magnet 52 disposed on each side of the first magnet 51 run in the X-direction.

Apart of a magnetic field of the second magnet 52 slips from the top face of the second magnet 52 under the bottom face of the second magnet 52, thereby closing on its own. Whereas a part of the magnetic field of the second magnet 52 thus closes on its own, it is difficult for a magnetic field of the first magnet 51 to close on its own. The line H connecting points where the horizontal component of a magnetic field between the first magnet 51 and the second magnet 52 is 0 therefore shifts outward in the Y-direction as the distance from the magnet unit 5 grows in the Z-direction.

As illustrated in FIG. 2A, the magnetic field of the first magnet 51 is smaller at the ends of the magnet unit 5 in the X-direction than the magnetic field of the second magnet 52. Therefore, the line H connecting points where the horizontal component of the magnetic field is 0 is closer to the first magnet 51 than in any other parts.

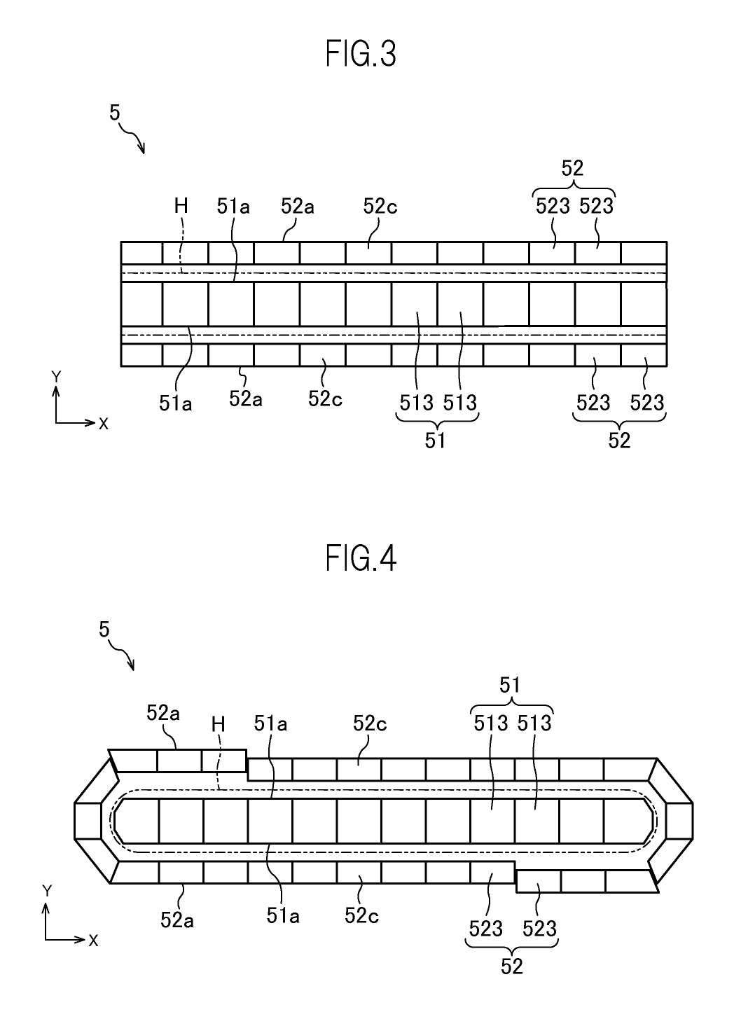

FIGS. 3 and 4 are each a plan view of the magnet unit 5 according to a modified example. Components that are duplicates of those in the embodiment described above are denoted by the same symbols in order to omit detailed descriptions. In the modified example of FIG. 3, the second magnet 52 is not closed at the ends in the X-direction, and is constituted of the pair of longer-side portions 52c that are disposed in each side of the first magnet 51 in the Y-direction and that run in the X-direction. In this mode, too, the same magnetic field profile as that of the embodiment illustrated in FIGS. 2A and 2B is obtained.

In the modified example of FIG. 4, some magnets 523 at the ends among the plurality of magnets 523 that constitute the pair of longer-side portions 52c of the second magnet 52 are placed further away from the first magnet 51 than the rest of the magnets 523. In this mode, too, the same magnetic field profile as that of the embodiment illustrated in FIGS. 2A and 2B is obtained and, in addition, the strength/weakness of a magnetic field and ultimately the strength/weakness of sputtering can be adjusted by shifting the positions of some of the magnets 523 suitably.

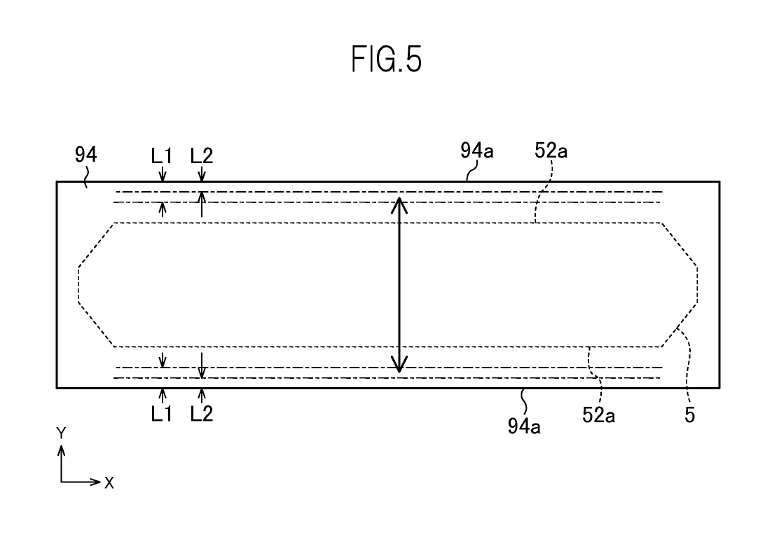

FIG. 5 is a diagram illustrating a first moving example of the magnet unit 5. The magnet unit 5 is placed under the target 94, which has a rectangular board shape, and is contained within the extent of the target 94 in plan view. The difference between the width of the target 94 in the X-direction and the width of the magnet unit 5 in the X-direction is relatively small, whereas the difference between the width of the target 94 in the Y-direction and the width of the magnet unit 5 in the Y-direction is relatively large.

Dashed lines in FIG. 5 represent edges of the magnet unit 5. The edges of the magnet unit 5 mean edges of a magnetic portion and, in the case of the magnet unit 5 that is described above with reference to FIGS. 2A and 2B, correspond to edges 52a of the second magnet 52.

The motor 8 which drives the magnet unit 5 swings the magnet unit 5 in the Y-direction as indicated by arrows in FIG. 5 while magnetron sputtering is being executed, in order to enhance the utilization efficiency of the target 94. The motor 8 is applied with a current from a controller (not shown) so that the magnet unit 5 moves back and forth within a specified range.

The motor 8 which drives the magnet unit 5 is controlled so as to reduce the closest distance between an edge 52a of the magnet unit 5 and an edge 94a of the target 94 in the Y-direction as the amount of the target 94 used increases. For example, the magnet unit 5 is initially swung within a range in which the closest distance between an edge 52a of the magnet unit 5 in the Y-direction and an edge 94a of the target 94 in the Y-direction is L1, and within a range in which the closest distance is L2 which is shorter than L1 as the amount of the target 94 used increases.

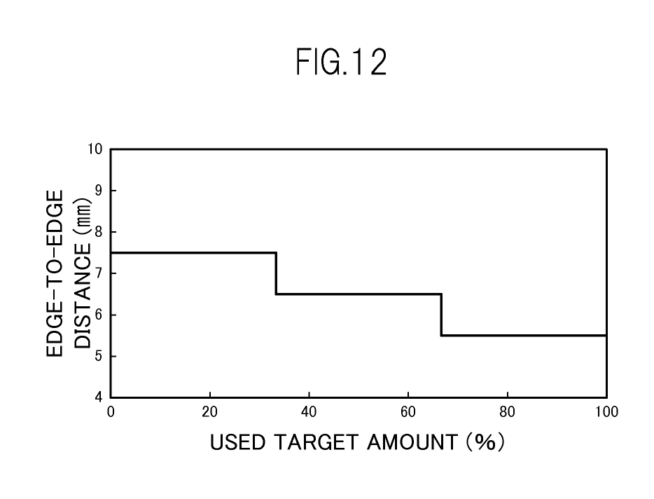

The closest distance is reduced, for example, in stages with the increase in the amount of the target 94 used as shown in FIG. 12. The present implementation is not limited thereto and the closest distance may be reduced linearly. The amount of the target 94 used is managed in the form of, for example, the product of power (kW) output from the power source 11 in order to induce plasma and the length of time (h) for which the power is kept output. The present implementation is not limited thereto and the amount of the target 94 used may be managed simply in the form of total sputtering time.

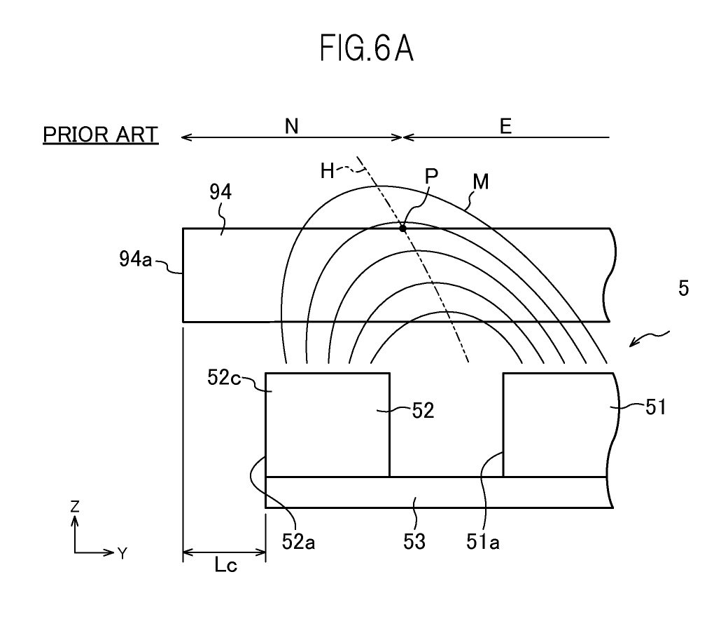

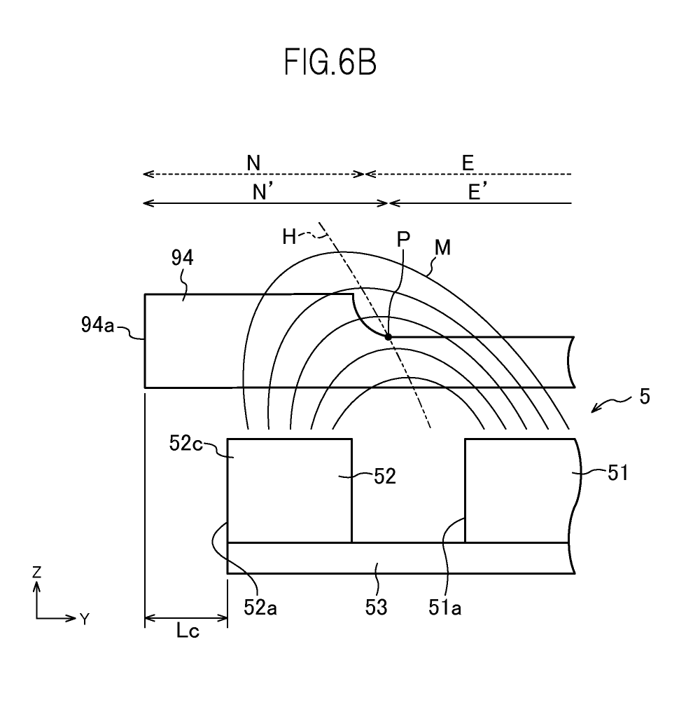

Before describing actions and effects of this embodiment, the related art in which a closest distance Lc is not changed is described with reference to FIGS. 6A and 6B. A point on which plasma is concentrated most in magnetron sputtering is a point where the horizontal component of a magnetic field is 0. Therefore, as illustrated in FIG. 6A, a point P where the target 94 is sputtered most is an intersecting point between the line H which connects points where the horizontal component of a magnetic field is 0 and the top face of the target 94. However, because a point where the horizontal component of a magnetic field is 0 shifts outward in the Y-direction as the distance from the top face of the magnet unit 5 grows in the Z-direction, a decrease in the thickness of the target 94 which accompanies an increase in the amount of the target 94 used leads to an inward shift in the Y-direction of the point P where the target 94 is sputtered most as illustrated in FIG. 6B. Consequently, an erosion region E′ which is sputtered by plasma shrinks inward in the Y-direction and a non-erosion region N′ which is not sputtered by plasma expands inward in the Y-direction.

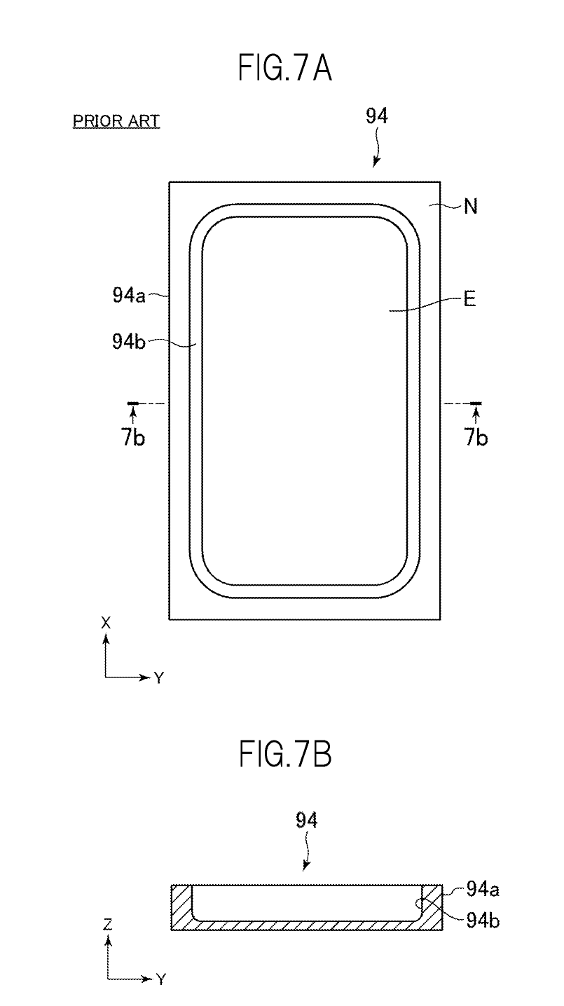

FIGS. 7A and 7B are respectively a plan view and sectional view of the target 94 according to the related art. The top face of the target 94 is gradually hollowed due to sputtering to form a concave surface as a whole. With the progress of sputtering (i.e., the increase in the amount of the target 94 used), the distance between an outer stretch 94b of the region where the target 94 is sputtered and edges 94a of the target 94 increases gradually.

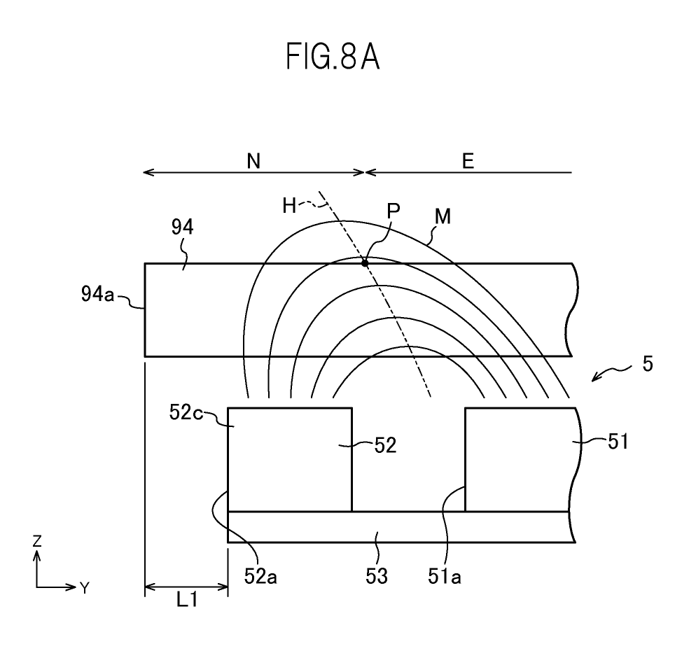

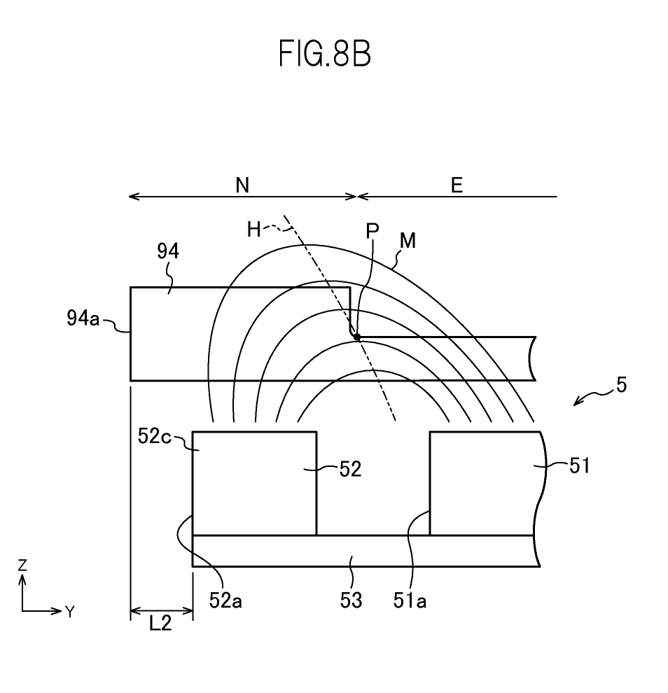

In contrast, this embodiment reduces the closest distance between an edge of the magnet unit 5 and an edge of the target 94 in the Y-direction from L1 to L2 with the increase in the amount of the target 94 used as illustrated in FIGS. 8A and 8B. This prevents the point P where the target 94 is sputtered most from shifting inward in the Y-direction as illustrated in FIG. 8B, despite a decrease in the thickness of the target 94 which is due to the increase in the amount of the target 94 used. As a result, the shrinkage of an erosion region E and the expansion of a non-erosion region N are prevented, thereby keeping the non-erosion region N substantially constant. Target utilization efficiency is enhanced as well.

In addition, the arcing count is also lowered because the point P where the target 94 is sputtered most (i.e., a point on which plasma is concentrated most) is prevented from approaching the edge 94a of the target 94 in the Y-direction in FIGS. 8A and 8B despite the reduction of the closest distance from L1 to L2. It is preferred to prevent the point P where the target 94 is sputtered most from changing in the Y-direction when the closest distance is reduced from L1 to L2.

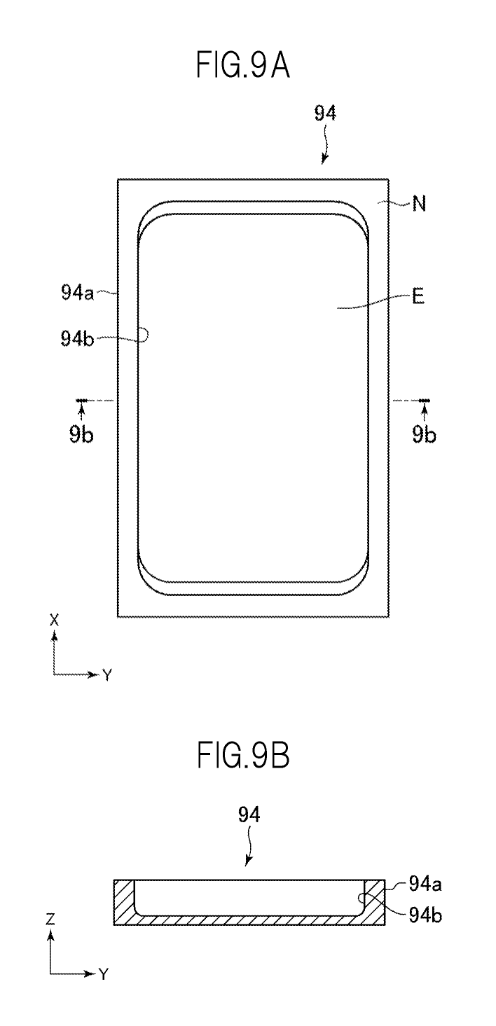

FIGS. 9A and 9B are respectively a plan view and sectional view of the target 94 according to this embodiment. In this embodiment, the distance between the outer stretch 94b of the region in which the target 94 is sputtered and the edges 94a of the target (at least the edges 94a of the target 94 in the Y-direction) is substantially constant regardless of the progress of sputtering (i.e., the increase in the amount of the target 94 used).

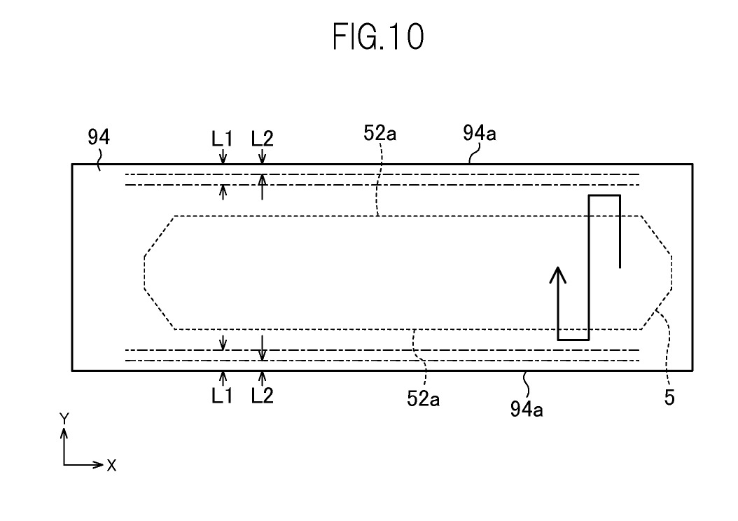

FIG. 10 is a diagram illustrating a second moving example of the magnet unit 5. In this example, the motor 8 which drives the magnet unit 5 swings the magnet unit 5 in the X-direction and the Y-direction as indicated by arrows in FIG. 10 while magnetron sputtering being executed. Specifically, the magnet unit 5 repeats the act of moving from one end in the Y-direction to the other end, moving in the X-direction, moving from the other end in the Y-direction to the one end, and then moving in the X-direction. The magnet unit 5 thus moves in a meandering fashion (i.e., moves back and forth in the Y-direction and proceeds in the X-direction).

In this example, too, the magnet unit 5 is swung so that the closest distance in the Y-direction between the edge 52a of the magnet unit 5 in the Y-direction and the edge 94a of the target 94 in the Y-direction is reduced from L1 to L2 as the amount of the target 94 used increases as in the first moving example illustrated in FIG. 5 and FIGS. 8A and 8B. The expansion of the non-erosion region N is thus prevented and the arcing count is lowered in this example as well. Target utilization efficiency is also enhanced.

Arcing hardly occurs at the ends of the magnet unit 5 in the X-direction because, as illustrated in FIG. 2A, the magnetic field between the first magnet 51 and the second magnet 52 is relatively small at the ends and the line H connecting points where the horizontal component of a magnetic field is 0 is closer to the first magnet 51 at the ends than in any other parts. For that reason, this example reduces the closest distance in the Y-direction alone with the increase in the amount of the target 94 used, and ignores the closest distance in the X-direction even if the closest distance in the X-direction becomes shorter than the closest distance in the Y-direction.

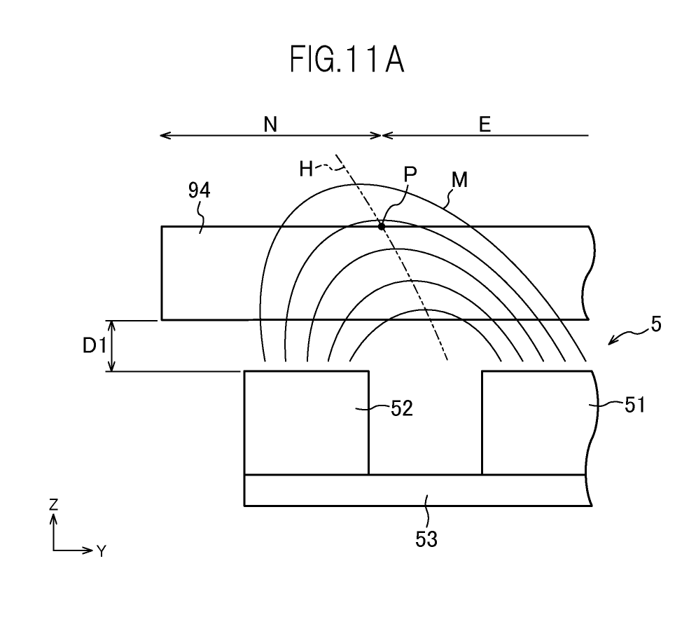

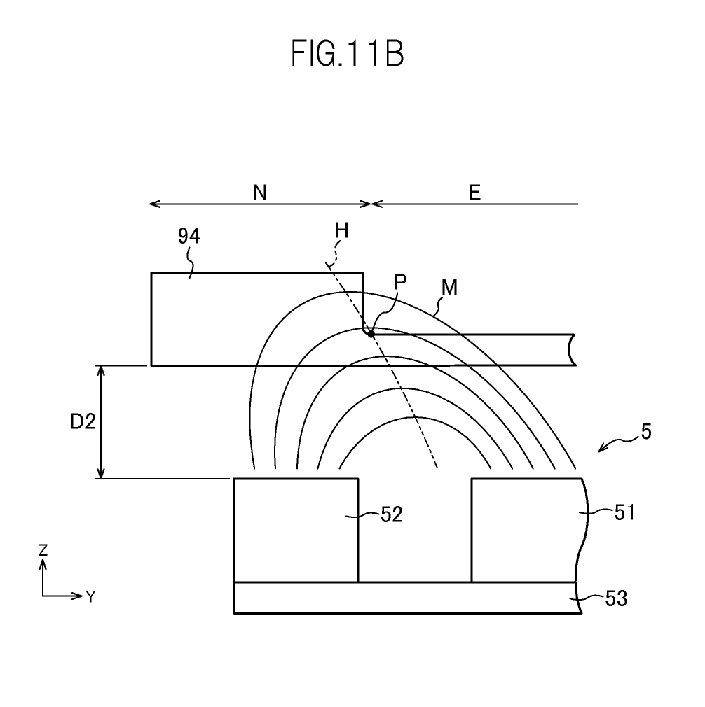

FIGS. 11A and 11B are diagrams illustrating a third moving example of the magnet unit 5. This example increases the closest distance between the magnet unit 5 and the target 94 in the Z-direction as the amount of the target 94 used increases. For example, the closest distance between the magnet unit 5 and the target 94 in the Z-direction is initially D1, and is changed to D2 which is longer than D1 with the increase in the amount of the target 94 used. This prevents the point P where the target 94 is sputtered most from shifting inward in the Y-direction as illustrated in FIG. 11B, despite the decrease in the thickness of the target 94 which is due to the increase in the amount of the target 94 used. As a result, the shrinkage of the erosion region E and the expansion of the non-erosion region N are prevented. The utilization efficiency of the target 94 is consequently enhanced as well.

In addition, the arcing count is also lowered because the point P where the target 94 is sputtered most (i.e., a point on which plasma is concentrated most) is prevented from shifting outward in the Y-direction despite the increase of the closest distance from D1 to D2. It is preferred to prevent the point P where the target 94 is sputtered most from changing in the Y-direction when the closest distance is increased from D1 to D2. In this example, the magnet unit 5 may be swung in the Z-direction while magnetron sputtering is being executed, in order to enhance the utilization efficiency of the target 94.

The embodiment of the present implementation has now been disclosed. However, the scope of the present invention is not limited to the embodiment and the modified examples and also includes other embodiments described below.

An embodiment of the present implementation includes a magnet unit which includes a first magnet having a first polarity on its face that is opposed to a face of a target opposite from a target face where the target is sputtered, and a second magnet having a second polarity on its face that is opposed to the face of the target opposite from the target face where the target is sputtered. The magnet unit is arranged so that a point where the horizontal component of a magnetic field generated between the first magnet and the second magnet is 0 is slanted toward the second magnet side as a distance from the face of the first magnet or from the face of the second magnet to the target decreases, in other words, the distance from the magnet unit grows. Another embodiment of the present implementation is a thin film manufacturing method for forming a thin film from an oxide by the sputtering of a target with the use of this magnet unit, or relates to a thin film manufacturing device that includes this magnet unit.

Sputtering is executed by controlling the target or the magnet unit so as not to expand a non-erosion region, where the target is not sputtered, as much as possible. In other words, when a thin film is manufactured by the sputtering of the target, the target or the magnet unit is controlled so that the shortest distance between an outer stretch of a region in which the target is sputtered and edges of the target is adjusted to be substantially constant while the target is in use.

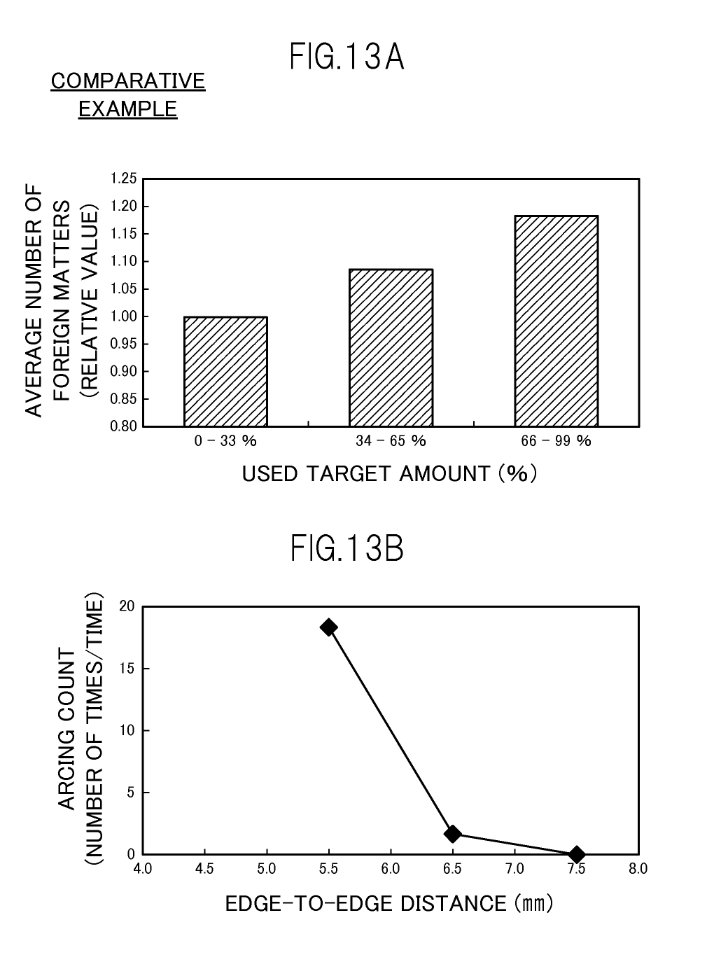

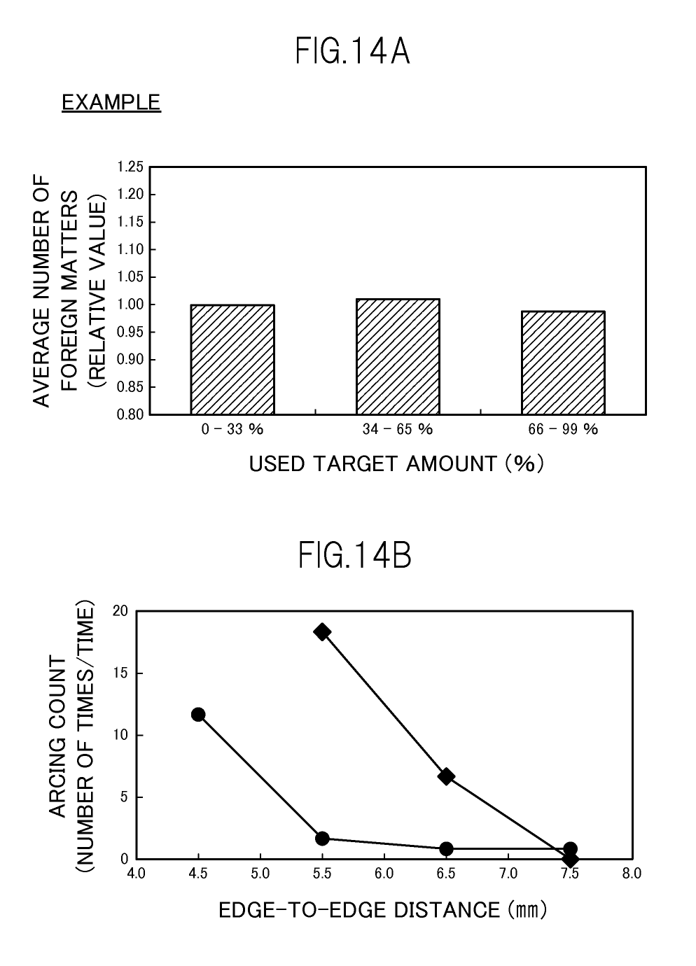

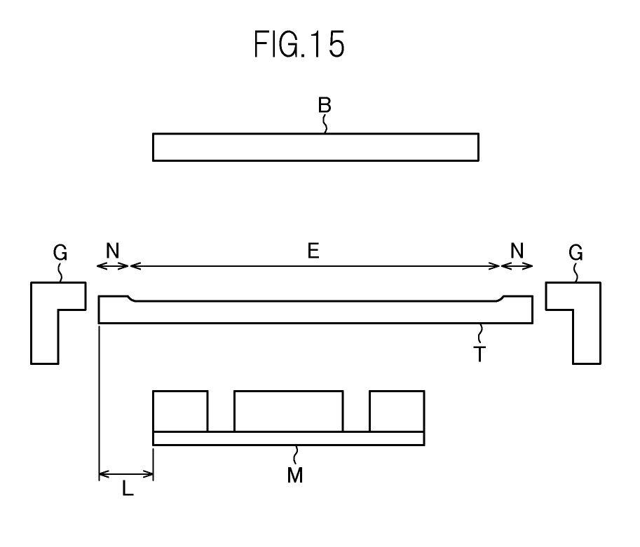

Experiments conducted to confirm the effects of the present implementation are described below. FIGS. 13A and 13B are graphs showing experiment results of Comparative Example. FIGS. 14A and 14B are graphs showing experiment results of Example. Example is the embodiment described above with reference to FIG. 5 and FIGS. 8A and 8B, and Comparative Example is the related art described above with reference to FIGS. 6A and 6B.

FIG. 13A and FIG. 14A are each a graph showing the relation between the amount of the target 94 used and the average number of foreign matters to be adhered to the substrate 92. The graphs set the average number of foreign matters at a used target amount of 0 to 33% as 1.00, and show a relative value that is relative thereto. A particle counter utilizing laser scattering was used to measure the number of foreign matters to be adhered to the substrate 92. As the amount of the target 94 used, the graphs show a percent ratio with the product of power and time (kW·h) at which a given weight is lost as a reference. The number of foreign matters was measured at the time a used target amount of 33% was reached, at the time a used target amount of 65% was reached, and a used target amount of 99% was reached, and then matters to be adhered to the non-erosion region N of the target 94 were removed.

In Comparative Example of FIG. 13A, the average number of foreign matters increased with the increase in the amount of the target 94 used. This is presumably because the non-erosion region N of the target 94 expanded with the increase in the amount of the target 94 used. Of the members placed inside the chamber 2, other members than the target 94 were subjected to surface treatment for keeping adhered matters from falling off. It can therefore be said that the increase in average number of foreign matters is correlated with the expansion of the non-erosion region N of the target 94.

In Example of FIG. 14A, on the other hand, the increase in the amount of the target 94 used hardly caused a change in average number of foreign matters. This is considered to indicate that the expansion of the non-erosion region N of the target 94 was prevented despite the increase in the amount of the target 94 used.

FIG. 13B and FIG. 14B are each a graph showing the relation between an edge-to-edge distance between an edge of the magnet unit 5 and an edge of the target 94 and an arcing count. FIG. 13B shows a case where the amount of the target 94 used was 5%. It is understood from this graph that the arcing count rises sharply when the edge-to-edge distance becomes lower than a certain threshold.

FIG. 14B shows a case where the amount of the target 94 used was 5% and a case where the amount of the target 94 used was 65%. It is understood from this graph that a threshold at which the arcing count rises becomes smaller as the amount of the target 94 used increases. In short, reducing the edge-to-edge distance with the increase in the amount of the target 94 used does not cause the arcing count to rise.

Described below are steps of manufacturing a liquid crystal display device with the use of the thin film manufacturing device 1 according to this embodiment. First, a TFT substrate which includes thin-film transistors, gate lines, data lines, and pixel electrodes is manufactured. At least some of these conductors are formed from a transparent conductive film made of ITO or the like. The transparent conductive film is formed by executing magnetron sputtering in the thin film manufacturing device 1 according to this embodiment. A CF substrate which includes color filters is manufactured next. A liquid crystal is then injected between the TFT substrate and the CF substrate, to thereby manufacture a liquid crystal display panel. Thereafter, a liquid crystal display device is manufactured by building circuits and other parts on the liquid crystal display panel.

This concludes a description of the embodiment of the present implementation. The present implementation, however, is not limited to the embodiment described above and it should be understood that various modifications could be made by the skilled in the art.

For instance, while the magnet unit 5 is moved relative to the target 94 in the embodiment described above, the present implementation is not limited thereto and the target 94 may be moved relative to the magnet unit 5. In addition, even when the thin film manufacturing device 1 does not have a mechanism for swinging the magnet unit 5, the closest distance between an edge of the magnet unit 5 and an edge of the target 94 can be varied by, for example, replacing the magnet unit 5 of one size with the magnet unit 5 of another size that suits the amount of the target 94 used.

While there have been described what are at present considered to be certain embodiments of the implementation, it will be understood that various modifications may be made thereto, and it is intended that the appended claims cover all such modifications as fall within the true spirit and scope of the implementation.

1. A thin film manufacturing method for forming a thin film that is made of an oxide by sputtering of a target, the thin film manufacturing method comprising:
placing a magnet unit which comprises a first magnet and a second magnet, the first magnet having a first polarity on its face that is opposed to a face of the target opposite to a target face where the target is sputtered, the second magnet having a second polarity on its face that is opposed to the face of the target opposite to the target face where the target is sputtered, the second magnet being disposed on each side of the first magnet; and
reducing a closest distance between an edge of the magnet unit and an edge of the target in an in-plane direction as an amount of the target used increases.

2. The thin film manufacturing method according to claim 1,
wherein the first magnet is formed to have a belt shape with longer sides, and
wherein the edge of the magnet unit is an edge of the second magnet, which is substantially parallel to the longer sides of the first magnet.

3. The thin film manufacturing method according to claim 1, wherein the magnet unit is swung in the in-plane direction.

4. The thin film manufacturing method according to claim 1, wherein at least one of the first magnet and the second magnet comprises a plurality of aligned magnets.

5. The thin film manufacturing method according to claim 1, wherein the first magnet has a length in a direction perpendicular to longer sides of the first magnet, which is substantially equal to a total length in the perpendicular direction of the second magnet disposed on each side of the first magnet, in a plane of the magnet unit.

6. The thin film manufacturing method according to claim 1, wherein the thin film is made of indium tin oxide.

7. A thin film manufacturing method for forming a thin film that is made of an oxide by sputtering of a target, the thin film manufacturing method comprising:
placing a magnet unit which comprises a first magnet and a second magnet, the first magnet having a first polarity on its face that is opposed to a face of the target opposite to a target face where the target is sputtered, the second magnet having a second polarity on its face that is opposed to the face of the target opposite to the target face where the target is sputtered, the second magnet being disposed on each side of the first magnet; and
increasing a closest distance between the magnet unit and the target in an out-of-plane direction as an amount of the target used increases.

8. A thin film manufacturing method for forming a thin film that is made of an oxide by sputtering of a target, the thin film manufacturing method comprising:
placing a magnet unit which comprises a first magnet and a second magnet, the first magnet having a first polarity on its face that is opposed to a face of the target opposite to a target face where the target is sputtered, the second magnet having a second polarity on its face that is opposed to the face of the target opposite to the target face where the target is sputtered, and arranging the magnet unit so that a point where a horizontal component of a magnetic field generated between the first magnet and the second magnet is zero is slanted toward the second magnet side as a distance from one of the face of the first magnet and the face of the second magnet to the target decreases; and
controlling one of the target and the magnet unit so that a shortest distance between an outer stretch of a region in which the target is sputtered and edges of the target is substantially constant.

9. A liquid crystal display device manufacturing method, comprising manufacturing a thin film by the thin film manufacturing method according to claim 1.

10. A thin film manufacturing device for forming a thin film that is made of an oxide by sputtering of a target, the thin film manufacturing device comprising:
a magnet unit which comprises a first magnet and a second magnet, the first magnet having a first polarity on its face that is opposed to a face of the target opposite to a target face where the target is sputtered, the second magnet having a second polarity on its face that is opposed to the face of the target opposite to the target face where the target is sputtered, the second magnet being disposed on each side of the first magnet; and
swinging means for swinging one of the target and the magnet unit relative to another thereof, the swinging means reducing a closest distance between an edge of the magnet unit and an edge of the target in an in-plane direction as an amount of the target used increases.

11. A liquid crystal display device manufacturing method, comprising manufacturing a thin film by the thin film manufacturing method according to claim 7.

12. A liquid crystal display device manufacturing method, comprising manufacturing a thin film by the thin film manufacturing method according to claim 8.
